(19) United States
(12) Patent Application Publication
(10) Pub. No.: US 2014/0202515 A1
(43) Pub. Date: Jul. 24, 2014

(54) BOOSTER FILMS FOR SOLAR PHOTOVOLTAIC SYSTEMS

(71) Applicant: Michael A. Haase, Saint Paul, MN (US)

(72) Inventor: Michael A. Haase, Saint Paul, MN (US)

(73) Assignee: 3M Innovative Properties Company, St Paul, MN (US)

(21) Appl. No.: 14/126,491

(22) PCT Filed: May 31, 2012
(86) PCT No.: PCT/US12/40066

§ 371 Date: Mar. 17, 2014

Related U.S. Application Data
(60) Provisional application No. 61/497,688, filed on Jun. 16, 2011.

(51) Int. Cl. H01L 31/042; H01L 31/077; H01L 31/0368

(52) U.S. Cl. CPC H01L 31/042; H01L 31/0368; H01L 31/077
USPC 136/244; 136/258; 136/255

(57) ABSTRACT

We describe stacked photovoltaic modules, and components thereof, in which at least one booster cell is combined with at least one primary cell in a stacked configuration. The booster cell may be in the form of a polycrystalline film disposed on a transparent substrate, such as a glass substrate, and the film may be patterned to form multiple booster cells. The booster cell includes an n-type layer and a p-type layer; the n-type layer may include polycrystalline zinc sulfide (ZnS), and the p-type layer may include polycrystalline zinc telluride (ZnTe). The n-type layer may have a band gap energy of at least 3.5 eV, and the p-type layer may have a band gap energy of at least 2 or at least 2.2 eV, or in a range from 2.2 to 2.3 eV. An intrinsic layer, also comprising polycrystalline ZnTe, may reside between the n-type and p-type layers.

### FIELD OF THE INVENTION

This invention relates generally to optical-to-electrical conversion devices such as photovoltaic solar cells, and associated articles, systems, and methods.

### BACKGROUND

The idea of deriving electrical power directly from sunlight has been around for some time now. It is an idea that has grown in popularity as energy demand throughout the world has continued to rise, and as concerns have been raised regarding negative aspects of other forms of power generation. Photovoltaic systems put this idea into practice.

Over the years, a wide variety of photovoltaic systems have been constructed and/or proposed. At the heart of each such system is a semiconductor wafer, film, or other extended structure. The semiconductor structure absorbs at least a portion of incident sunlight, or light from another light source, and converts at least a portion of the absorbed optical energy directly into electrical power. In most cases, the semiconductor structure comprises a diode formed by a p- and n-type material layer. Energy conversion occurs when an absorbed photon of sunlight generates an electron-hole pair, and the electron or the hole traverses the junction formed by the semiconductor material layers.

As a result of this energy conversion mechanism, most semiconductor structures in photovoltaic systems can be considered to be current sources, with more current being generated as the intensity or flux of incident sunlight increases. The current is provided with a voltage drop that depends on the load that is connected across the terminals of the structure. If a “zero load” is provided (i.e., short circuit condition, or Z=0), a current I_{sc} flows, with zero voltage across the terminals. If an infinite load is provided (i.e., open circuit condition, or Z=∞), no current flows, and an open circuit voltage V_{oc} develops across the terminals. Between these extremes, maximum electrical power is generated for a load of a particular impedance Zₘₚ, at which a current Iₘₚ flows across a voltage Vₘₚ. Note that 0<Iₘₚ<I_{sc}, and 0<Vₘₚ<V_{oc}.

One figure of merit used to assess the performance of a given photovoltaic system is “conversion efficiency”—the useable electrical power P_{elec} provided by the system divided by the optical power Pₒₚₜ incident on the system. The (maximum) useable electrical power is related to the current and voltage quantities discussed above by the relation P_{elec}=Iₘₚ*Vₘₚ. The conversion efficiency of most commercial systems is relatively low, e.g., less than 30%, and in many cases is on the order of 20% or 15% or less.

Various design features have been proposed to improve conversion efficiency of photovoltaic systems. One such feature involves multijunction embodiments, wherein two or more distinct semiconductor structures are stacked together. A first semiconductor diode cell with a higher band gap energy is located above or in front of one or more second semiconductor diode cells with lower band gap energies. When polychromatic light is incident on the first cell, short wavelength light is absorbed, generating a large photovoltage. Longer wavelength light passes through the first cell and is transmitted to the second cell, where it is absorbed and generates a smaller photovoltage. The first cell is sometimes referred to as a booster cell, and the second cell is sometimes referred to as a primary cell. Electrical power generated by these different cells is then converted to useable electrical power with appropriate circuitry.

At least three types of stacked configurations have been described in the art: one in which the cells are mechanically stacked, but electrically isolated from each other; one in which the cells are mechanically stacked, but electrically connected in series (this assumes careful design so that each of the cells provides the same current); and one, referred to as monolithic multijunction cells, in which the cells are epitaxially grown on top of each other and electrically connected in series by tunnel junctions.

### BRIEF SUMMARY

We have developed a new family of booster cells that are relatively easy to manufacture and that can be readily combined with currently popular primary cells, in particular, at least primary cells made from monocrystalline silicon, multicrystalline silicon, or polycrystalline cadmium telluride, so as to provide a stacked arrangement with significantly improved overall efficiency. The booster cell may be or include a polycrystalline film disposed on a glass substrate or other suitable transparent substrate, and the film may be patterned to form multiple booster cells. The polycrystalline film may be deposited and patterned using manufacturing processes that are typically faster and cheaper than processes involving monocrystalline materials. Each booster cell may include an n-type layer and a p-type layer. The n-type layer may include polycrystalline zinc sulfide (ZnS), and may have a band gap energy of at least 3.5 eV or at least 3.6 eV, and the p-type layer may include polycrystalline zinc telluride (ZnTe), and may have a band gap energy of at least 2 or at least 2.2 eV, or it may be in a range from 2 to 3 eV, or from 2 to 2.5 eV, or from 2.2 to 2.3 eV. An intrinsic layer, which may also be or include polycrystalline ZnTe, may reside between the n-type and p-type layers. In this context, by “intrinsic” we mean not intentionally doped with donors or acceptors. Unless otherwise specified herein, if a material is said to include or comprise ZnS or ZnTe, such material may consist of or consist essentially of bulk crystalline ZnS or ZnTe in non-alloy form (but optionally with one or more suitable dopant to provide n-type or p-type material), respectively, but such material may also be or include an alloy of ZnS or ZnTe, respectively (again, optionally with one or more suitable dopant), such alloys also including in the lattice structure one or more other atoms from columns II or VI of the periodic table, the other atoms substituting for some of the Zn, S, and/or Te atoms in the lattice.

We describe, therefore, among other things, stacked photovoltaic modules and components thereof in which at least one booster cell is combined with at least one primary cell in a stacked configuration. The booster cell may be in the form of a polycrystalline film disposed on a transparent substrate, such as a glass substrate, and the film may be patterned to form multiple booster cells. The booster cell includes an n-type layer and a p-type layer. The n-type layer may include polycrystalline zinc sulfide (ZnS), and the p-type layer may include polycrystalline zinc telluride (ZnTe). The n-type layer may have a band gap energy of at least 3.5 eV or at least 3.6 eV, and the p-type layer may have a band gap energy of at least 2 or at least 2.2 eV, or it may be in a range from 2 to 3 eV, or from 2 to 2.5 eV, or from 2.2 to 2.3 eV. An intrinsic layer, also comprising polycrystalline ZnTe, may reside between the n-type and p-type layers.

We also disclose components for use in solar photovoltaic modules. Such components may include a transparent substrate such as a glass substrate, and a thin-film photovoltaic booster cell formed on the substrate. The booster cell may include an n-type layer and a p-type layer. The n-type layer may include polycrystalline zinc sulfide (ZnS) and have a band gap energy of at least 3.5 eV or at least 3.6 eV. The p-type layer may include polycrystalline zinc telluride (ZnTe). The booster cell may be adapted to generate electricity by absorbing solar radiation in a first wavelength range, and transmit solar radiation in a second wavelength range greater than the first wavelength range.

The p-type layer may have a band gap energy of at least 2 eV, or at least 2.2 eV, or it may be in a range from 2 to 3 eV, or from 2 to 2.5 eV, or from 2.2 to 2.3 eV. In the n-type layer, the polycrystalline

ZnS material may be doped with aluminum (Al) or chlorine (Cl), and in the p-type layer, the polycrystalline ZnTe material may be doped with nitrogen (N). The booster cell may also include an intrinsic layer disposed between the n-type layer and the p-type layer, and the intrinsic layer may include polycrystalline ZnTe. The intrinsic layer may have a band gap energy in a range from 2.2 to 2.3 eV. The intrinsic layer may have a thickness in a range from 0 to 1000 nm, or from 100 to 500 nm.

The booster cell may be one of an array of booster cells formed on the substrate, and each of the booster cells may include an n-type layer comprising polycrystalline ZnS and a p-type layer comprising polycrystalline ZnTe. A component containing an array of such booster cells may be used to construct a solar module by combining it with an array of photovoltaic primary cells disposed to receive solar radiation transmitted by the component, the primary cells each being adapted to generate electricity by absorbing solar radiation in the second wavelength range. In such a solar module, the array of primary cells may comprise monocrystalline silicon, multicrystalline silicon, and/or polycrystalline cadmium telluride. Furthermore, the booster cells may be configured and arranged such that each of the booster cells occupies an area A1 and, when fully illuminated, provides a first voltage V1 for a first load of maximum power dissipation connected across the plurality of booster cells, and each of the primary cells occupies an area A2 and, when fully illuminated, provides a second voltage V2 for a second load of maximum power dissipation connected across the array of primary cells, and the quantity (V1/A1) may be substantially equal to (V2/A2). For example, the parameters may satisfy the condition 0.8≦(V1*A2)/(V2*A1)≦1.2, or 0.9≦(V1*A2)/(V2*A1)≦1.1. In some embodiments it is advantageous to assure that 1.0≦(V1*A2)/(V2*A1).

We also describe solar modules that include an array of photovoltaic booster cells and an array of photovoltaic primary cells. The array of booster cells may be adapted to generate electricity by absorbing solar radiation in a first wavelength range, and to transmit solar radiation in a second wavelength range greater than the first wavelength range. The array of primary cells may be disposed to receive solar radiation transmitted by the array of booster cells, and to generate electricity by absorbing solar radiation in the second wavelength range. The booster cells may comprise polycrystalline zinc telluride (ZnTe), and the primary cells may comprise monocrystalline silicon, multicrystalline silicon, and/or polycrystalline cadmium telluride (CdTe).

Each booster cell may include a p-type layer comprising polycrystalline zinc telluride (ZnTe), which may have a band gap energy of at least 2 eV, or at least 2.2 eV, or it may be in a range from 2 to 3 eV, or from 2 to 2.5 eV, or from 2.2 to 2.3 eV. Each booster cell may also include an n-type layer comprising polycrystalline zinc sulfide (ZnS), which may have a band gap energy of at least 3.5 eV, or at least 3.6 eV. In the n-type layer, the polycrystalline ZnS may be doped with aluminum (Al) or chlorine (Cl), and in the p-type layer, the polycrystalline ZnTe may be doped with nitrogen (N). Each booster cell may also include an intrinsic layer disposed between the n-type layer and the p-type layer, the intrinsic layer comprising polycrystalline ZnTe. The intrinsic layer may have a thickness in a range from 0 to 1000 nm, or from 100 to 500 nm.

The module may also include a first glass substrate on which the array of booster cells is disposed, and a second glass substrate on which the array of primary cells is disposed. The primary cells may comprise monocrystalline silicon, multicrystalline silicon, and/or polycrystalline cadmium telluride (CdTe). The booster cells may be configured and arranged such that each of the booster cells occupies an area Al and, when fully illuminated, provides a first voltage V1 for a first load of maximum power dissipation connected across the plurality of booster cells, and each of the primary cells occupies an area A2 and, when fully illuminated, provides a second voltage V2 for a second load of maximum power dissipation connected across the array of primary cells, and the quantity (V1/A1) may be substantially equal to (V2/A2). For example, the parameters may satisfy the condition 0.8≦(V1*A2)/(V2*A1)≦1.2, or 0.9≦(V1*A2)/(V2*A1)≦1.1. In some embodiments it is advantageous to assure that 1.0≦(V1*A2)/(V2*A1).

Related methods, systems, and articles are also discussed.

These and other aspects of the present application will be apparent from the detailed description below. In no event, however, should the above summaries be construed as limitations on the claimed subject matter, which subject matter is defined solely by the attached claims, as may be amended during prosecution.

### BRIEF DESCRIPTION OF THE DRAWINGS

FIG. 1 is a schematic perspective view of a solar module;

FIG. 2 is a schematic side or sectional view of a solar cell, the solar cell being illuminated with polychromatic light containing long and short wavelengths;

FIG. 3 is a schematic side or sectional view of a device in which a secondary solar cell, sometimes referred to herein as a booster cell or booster film, is disposed in front of a primary solar cell to form a stacked structure;

FIG. 4 is a schematic side or sectional view of a secondary cell or booster film sandwiched together with a primary cell to form a stacked solar module;

FIG. 5a is a graph of modeled conversion efficiency for a stacked solar module in which the primary solar cell is a 22% efficient silicon cell, and the booster cell is assumed to be ideal;

FIG. 5b is a graph similar to that of FIG. 5b, but wherein the booster cell is assumed to have significant losses;

FIG. 6 is a schematic side or sectional view of a solar module having a plurality of stacked cells;

FIGS. 7a-7f are a series of schematic side or sectional views of a booster cell component in various stages of manufacture;

FIG. 8a is a graph of modeled conversion efficiency for a stacked solar module in which the primary solar cell is a 12% efficient CdTe cell, and the booster cell is assumed to be ideal; FIG. 8b is a graph similar to that of FIG. 8b, but wherein the booster cell is assumed to have significant losses;

FIG. 9 is a schematic side or sectional view of a solar module having a plurality of stacked cells;

FIG. 10 is a schematic side or sectional view of a solar module having a plurality of stacked cells, showing electrical connections between cells and from the cells to a power combiner;

FIG. 11 shows, in schematic plan view, the physical layout and circuit layout of a primary cell component and corresponding layouts of a secondary cell component, the components being adapted for use in a stacked solar module, and shown separated from each other for clarity; and

FIG. 12 shows, in schematic plan view, the physical layout of a primary cell component, a booster cell component, and the combination thereof in a stacked solar module.

In the figures, like reference numerals designate like elements.

### DETAILED DESCRIPTION OF ILLUSTRATIVE EMBODIMENTS

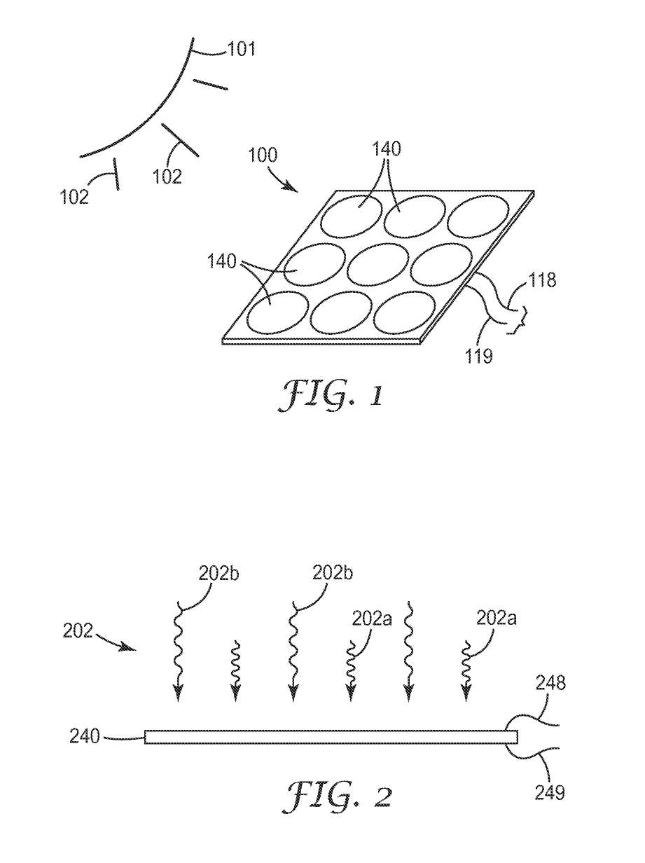

In FIG. 1, we see a schematic perspective view of a solar module 110. Visible and/or non-visible light 102 from the sun 101 or other suitable source of electromagnetic radiation falls on photovoltaic cells 140 that are part of the module. The cells 140, which may be arranged in a regular repeating array as shown, or any other suitable array, absorb at least a portion of the light 102 and convert the absorbed light directly into electrical power. The electrical power may be tapped by connecting an electrical load across output terminals 118, 119. The terminals 118, 119 typically connect to the cells 140 in an electrical series arrangement, but other arrangements are also contemplated. The cells 140 are preferably shaped and arranged with respect to each other on the module 110 to maximize useful area and minimize wasted area, i.e., minimize the amount of light that impinges on the module 110 without impinging on a cell 140.

A single photovoltaic cell 240, such as one of the cells 140 in FIG. 1, is shown schematically in FIG. 2. The cell 240 is shown illuminated with polychromatic light 202, the light 202 including both short wavelength light 202a and longer wavelength light 202b. The cell 240 may be a so-called “primary” cell discussed above, whereupon it may absorb both light 202a and light 202b, and convert the absorbed light directly into electrical power, which may be tapped via output terminals 248, 249.

The cell 240 has a diode structure (not shown in FIG. 2), with an n-type semiconductor layer, a p-type semiconductor layer, and an optional intrinsic semiconductor layer arranged to form a p-n or p-i-n junction. A photon of light that is absorbed by the cell produces an electron-hole pair, and electrical current is produced when the electron or the hole is swept across the junction.

The semiconductor material used to form the cell 240 is characterized by an energy difference between a valence band and a conduction band of the material, this difference being referred to as a band gap energy. One source of inefficiency in solar cells is the difference between the energy of an absorbed photon and the band gap energy of the semiconductor material. Monocrystalline or multicrystalline silicon, for example, has a band gap energy of about 1.1 electron volts (eV), which results in a maximum-power voltage of about 0.5V at a flux of one sun. “One sun”, in this regard, refers to the flux corresponding to Air Mass 1.5 Global (1000 W/m², AM1.5G) solar spectrum. Therefore, Si solar cells typically provide 0.5 eV or less of electrical energy per incident photon. If a photon of green light (λ=550 nm, energy=2.25 eV) is absorbed by the monocrystalline silicon and produces an electron-hole pair, most of the photon energy is dissipated or lost as heat: lost energy=2.25−0.5=1.75 eV. Lower energy light, such as a photon of infrared light of wavelength 900 nm (energy=1.38 eV), results in less lost energy in the same material: lost energy=1.38−0.5=0.88 eV.

Currently popular primary cells include cells made from monocrystalline silicon, cells made from multicrystalline silicon, and cells made from polycrystalline cadmium telluride. Monocrystalline silicon cells, at a flux of one sun, have a conversion efficiency in a range from about 17-25%. Multicrystalline silicon cells, at a flux of one sun, have a conversion efficiency in a range from about 15-20%.

Polycrystalline cadmium telluride (CdTe) cells have a band gap energy of about 1.45 eV, and, at a flux of one sun, have a conversion efficiency in a range from about 10-16% and generate a voltage Vₘₚ at the maximum power point of about 0.6 Volts.

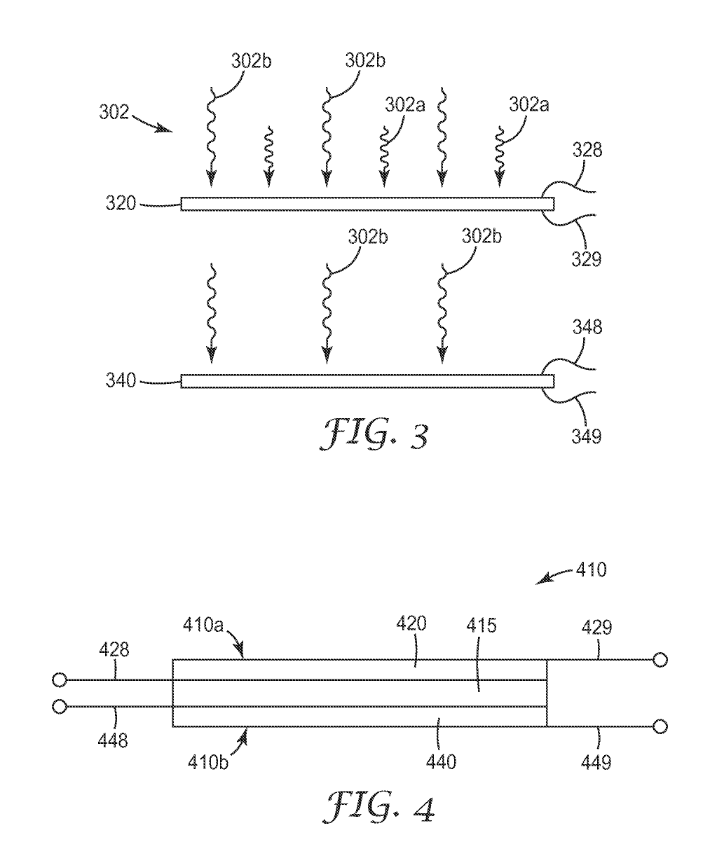

FIG. 3 shows a stacked arrangement or structure of photovoltaic cells. The stacked arrangement is formed by a secondary or booster cell 320 disposed over or in front of a primary cell 340. Polychromatic light 302, such as solar illumination, impinges on the arrangement, the light 302 including both short wavelength light 302a and longer wavelength light 302b. The booster cell 320 has a band gap energy that causes it to absorb only the short wavelength light 302a, and transmit the longer wavelength light 302b. Light absorbed by the booster cell 320 is converted directly into electrical power, which may be tapped via output terminals 328, 329. The primary cell 340 has a lower band gap energy that causes it to absorb the longer wavelength light 302b transmitted by the booster cell. Light absorbed by the primary cell 340 is converted directly into electrical power, which may be tapped via output terminals 348, 349.

The stacked arrangement of photovoltaic cells is typically constructed in the form of a solar module 410, shown schematically in FIG. 4. In the module 410, a booster cell 420 is sandwiched together with a primary cell 440. The booster cell 420 is disposed at or near a front side 410a of the module 410, and the primary cell 440 is disposed at or near a back or rear side 410b of the module. A spacer layer 415 may be filled with a transparent encapsulant to reduce reflection losses at interior surfaces, to increase thermal coupling for heat management purposes, and to preserve electrical isolation between the booster cell and the primary cell. Electrical power generated by the booster cell 420 may be tapped via output terminals 428, 429, and power generated by the primary cell 440 may be tapped via output terminals 448, 449. Note that the module 410 is a 4-wire device. In some cases, discussed further below, booster cells and primary cells can be designed such that terminals can be connected to effectively yield a 2-wire device. For example, in some cases, terminal 428 can be connected to terminal 448, and terminal 429 can be connected to terminal 449.

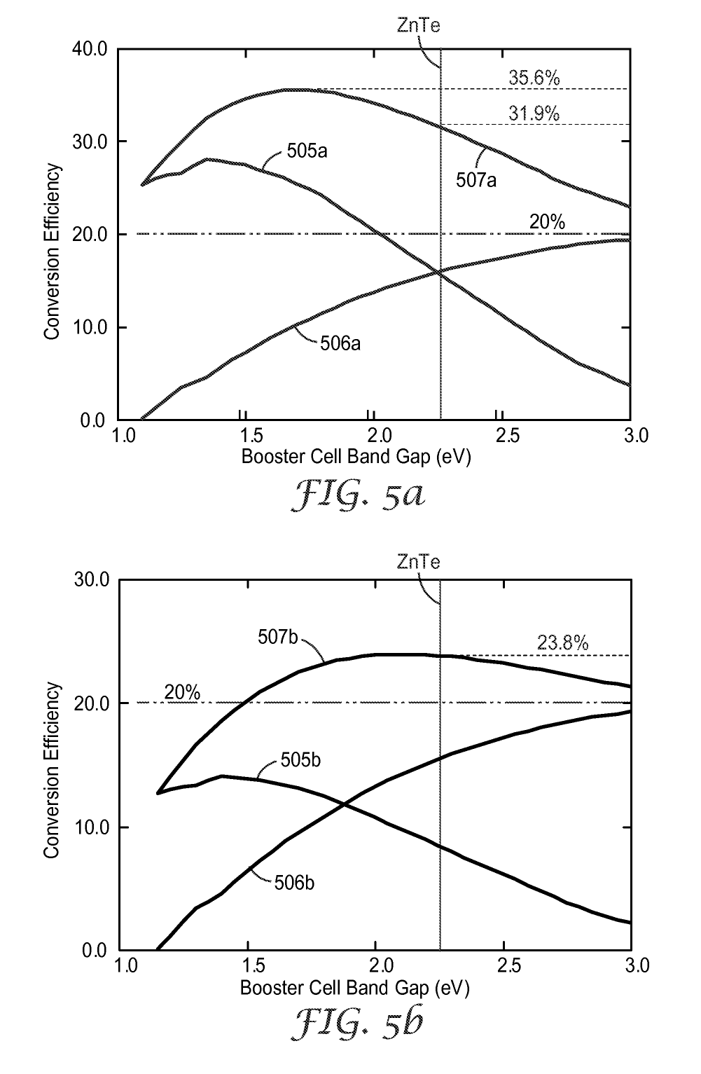

We have done modeling to assess the suitability of various types of booster cells with various types of primary cells. FIGS. 5a and 5b show the results of some of that modeling, for the case where the primary cell is composed of monocrystalline silicon or multicrystalline silicon. Monocrystalline silicon refers to single crystal silicon in which the crystal lattice is substantially continuous and unbroken, with no grain boundaries. Multicrystalline silicon, sometimes also referred to as polycrystalline silicon, or simply polysilicon, refers to silicon that is composed of moderately-sized crystallites (“grains”) of varying size and orientation, with grain boundaries therebetween. Multicrystalline silicon may have grain sizes ranging up to a few millimeters or even centimeters. Multicrystalline silicon may be distinguished from amorphous silicon by grain size, by mobility of the charge carriers, and by the absence of significant amounts of hydrogen which is used to passivate dangling bonds in amorphous silicon. Whether the silicon is monocrystalline or multicrystalline, suitable dopant material(s) is or are used to form a p-n or p-i-n junction so that the cell can generate electricity.

Monocrystalline silicon and multicrystalline silicon each have a band gap energy of about 1.1 eV, and can have conversion efficiencies of about 20%. For our modeling, we assumed a stacked structure in which a booster cell was placed in front of the silicon primary cell, and the combination was illuminated with light corresponding to the solar spectrum. The free variable used in the modeling was the band gap energy of the booster cell. For simplicity, the model assumed the booster cell transmitted all light of energy below the band gap energy, and absorbed all light above the band gap energy. For example, for a band gap energy for the booster cell of 1.5 eV (λ≈827 nm), solar radiation of wavelengths equal to or less than 827 nm would be absorbed by the booster cell, and solar radiation of wavelengths greater than 827 nm would be transmitted by the booster cell.

The model was similar to that reported in “Limiting efficiencies of ideal single and multiple energy gap terrestrial solar cells,” C. H. Henry, J. Appl. Phys., vol. 51 (August 1980). Initially, the model assumed the quantum efficiency of the booster cell was ideal, i.e., 100%. In this case, each photon that was absorbed in the booster cell was assumed to generate one quantum (electron and hole) of collected charge at zero bias voltage. The results for this ideal case are shown in FIG. 5a. In this figure, curve 505a shows the conversion efficiency of the booster cell by itself, curve 506a shows the conversion efficiency of the primary (monocrystalline Si or multicrystalline Si) cell by itself, and curve 507a shows the combined conversion efficiency for both cells. Several features of the curves are worth noting. Curve 506a for the primary cell has a value of zero at a booster cell band gap energy of 1.1 eV. This is logical, because the band gap energy of the primary cell was assumed to be 1.1 eV, and if the booster cell band gap energy is also 1.1 eV, then none of the light transmitted by the booster cell (in this case, light whose wavelength is 1127 nm or more) would be absorbed by the primary cell. Curve 506a also asymptotically approaches a conversion efficiency of 22% for increasing values of the booster cell band gap energy. This is also logical, because the conversion efficiency of the primary cell by itself was assumed to be 22%, and as the energy gap of the booster cell increases, it blocks (absorbs) less and less of the incident solar spectrum from reaching the primary cell.

We also include in FIG. 5a a vertical line at 2.25 eV, which is the band gap energy of bulk crystalline ZnTe, i.e., pure ZnTe rather than an alloy of ZnTe. Note that the maximum conversion efficiency of 36% for the combination of cells (curve 507a) occurs at a booster cell band gap energy of about 1.75 eV, which is very much less than 2.25 eV. This result of FIG. 5a would therefore lead persons of ordinary skill in the art away from considering materials comprising ZnTe as a reasonable option for a booster cell for use with a monocrystalline or multicrystalline silicon primary cell, because of the non-optimal performance of the combination of those cells. The person of ordinary skill would be led away from using, with those primary cells, booster cell materials comprising ZnTe and/or having a band gap energy of at least 2 eV, or at least 2.2 eV, or about 2.25 eV, or in a range from 2 to 3 eV, or from 2 to 2.5 eV, or from 2.2 to 2.3 eV.

In our modeling investigations, we did not stop our analysis after the results shown in FIG. 5a. We also considered an alternative scenario. The alternative scenario was based on the observation that state-of-the-art thin film photovoltaic cells that utilize another II-VI semiconductor material, namely, CdTe, operate at about half of their theoretical maximum efficiency.

We therefore modeled an alternative stacked solar module in which a booster cell was again placed in front of a silicon primary cell (monocrystalline or multicrystalline silicon, band gap energy of 1.1 eV, solo conversion efficiency of 22%), and the combination was again illuminated with light corresponding to the solar spectrum. The free variable used in the modeling was again the band gap energy of the booster cell, and the model assumed the booster cell transmitted all light of energy below the band gap energy, and absorbed all light above the band gap energy. In this alternative scenario, however, the model assumed a quantum efficiency for the booster cell of 50% rather than 100%. Every two photons that were absorbed in the booster cell were thus assumed to generate one quantum (electron and hole) of collected charge.

The results for this alternative case (lossy booster cell with monocrystalline or multicrystalline silicon primary cell) are shown in FIG. 5b. In this figure, curve 505b shows the conversion efficiency of the booster cell by itself, curve 506b shows the conversion efficiency of the primary (monocrystalline Si or multicrystalline Si) cell by itself, and curve 507b shows the combined conversion efficiency for both cells. Several features of the curves are worth noting. Curve 506b for the primary cell again has a value of zero at a booster cell band gap energy of 1.1 eV. This is to be expected using the same logic described above for FIG. 5a. Curve 506b also asymptotically approaches a conversion efficiency of 22% for increasing values of the booster cell band gap energy. This too is to be expected, based again on the logic described above for FIG. 5a.

Comparing FIGS. 5a and 5b, we also see that the maximum conversion efficiency for the combination of the booster cell and the primary cell in FIG. 5b, i.e., about 24.5%, is lower than that in FIG. 5a, i.e., about 36%. The lower efficiency value is logical based on the lossy booster cell assumed for FIG. 5b.

A more surprising difference between FIGS. 5a and 5b is the shift in the booster cell band gap energy at which the combination curves (507a, 507b) experience a maximum. In particular, the booster cell band gap energy that produces optimal conversion efficiency for the booster/primary cell combination shifts to substantially higher energies in FIG. 5b compared to FIG. 5a. The shift is such that the band gap energy of 2.25 eV, corresponding to non-alloy ZnTe, results in a conversion efficiency for the combination of cells that is at or near the peak of the curve 507b. We note from FIG. 5b that other materials comprising ZnTe that have somewhat different band gap energies, such as a band gap energy of at least 2 eV, or at least 2.2 eV, or about 2.25 eV, or in a range from 2 to 3 eV, or from 2 to 2.5 eV, or from 2.2 to 2.3 eV, would also produce relatively high overall conversion efficiency for the more realistic model of FIG. 5b. Band gap energies such as these may be achieved using alloys of ZnTe, e.g., materials that contain in the lattice structure one or more other atoms from columns II or VI of the periodic table, the other atoms substituting for some of the Zn and/or Te atoms in the lattice.

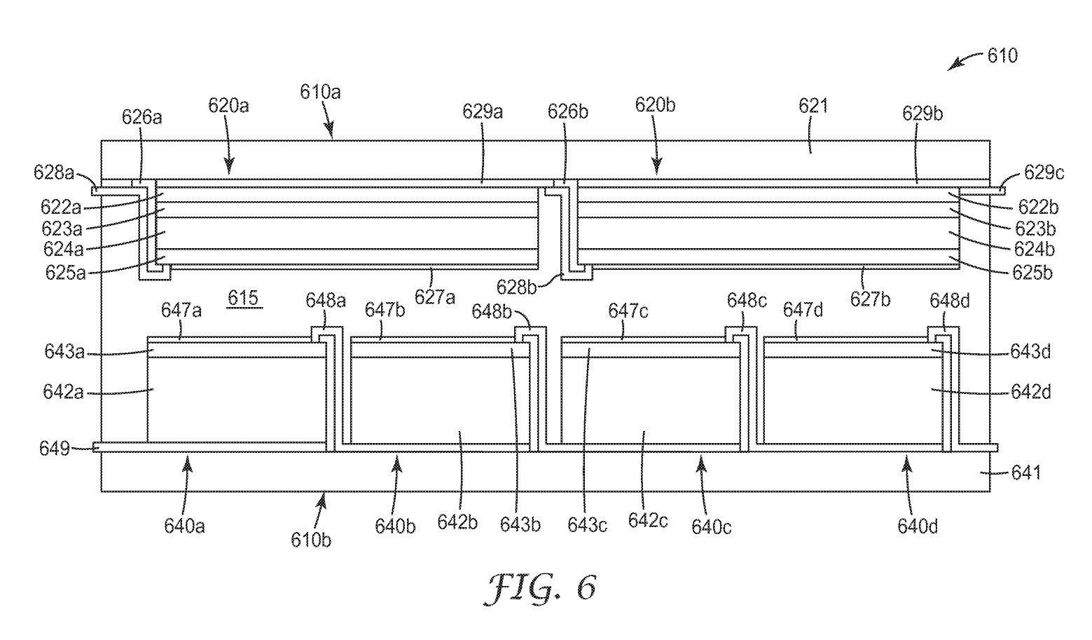

An exemplary solar module in which ZnTe-based booster cells are combined with primary photovoltaic cells in a stacked arrangement is shown schematically in FIG. 6. The solar module 610 can be considered to be the combination of a booster component, disposed at or near a front side 610a of the module 610, and an array of primary solar cells 640a, 640b, 640c, 640d, disposed at or near a back side 610b of the module. The booster component may comprise a transparent substrate 621, such as a rigid piece of glass or other suitable material, on which is formed an array or plurality of booster cells 620a, 620b. The term “substrate” in this regard refers to a body on which the cells are disposed or carried, regardless of whether the substrate is designed to be positioned in front of the cells (in which case the substrate may also be referred to as a superstrate) or behind the cells. Although only two booster cells and four primary cells are shown in the figure, the reader will understand that the module 610 may be extended in any in-plane direction to include more booster cells and/or primary cells as desired. A transparent encapsulant 615 may fill the space between the booster cells 620a, 620b and the primary cells 640a, 640b, 640c, 640d. The encapsulant may serve multiple functions, e.g., to reduce reflection losses at interior surfaces, to increase thermal coupling for heat management purposes, and to preserve electrical isolation between the booster cells and the primary cells. Ethylene vinyl acetate (EVA) and polyvinyl butyral (PVB) are examples of materials that may be used for these purposes, depending on system requirements and specifications.

The booster cells 620a, 620b may each comprise a transparent conductor 629a, 629b, an n-type layer 622a, 622b, an optional graded n-type layer 623a, 623b, an optional intrinsic layer 624a, 624b, a p-type layer 625a, 625b, and an anti-reflective layer or coating 627a, 627b, arranged as shown in the figure. These layers may be sequentially deposited on the substrate 621 using any suitable thin film deposition techniques and procedures, such as evaporation coating, sputtering, chemical vapor deposition, close-spaced sublimation (CSS), or the like, and may then be patterned by etching or other suitable means to form the separate, distinct cells.

The transparent conductor 629a may be or include indium tin oxide (ITO) or any other suitable electrically conductive material. The layers 622a-b, 623a-b, 624a-b, and 625a-b are all composed of semiconductor materials, but with different doping levels and/or compositions as appropriate to provide the desired p-i-n junction (or p-n junction) diode structure. These semiconductor layers may all be deposited using CSS or other suitable techniques that provide polycrystalline layer morphology.

Presently, the CSS technique is capable of forming high quality polycrystalline layers of suitable thicknesses and sizes (areas) at reasonable speeds and at relatively low manufacturing costs compared to single crystal device fabrication. In an exemplary embodiment, the n-type layers 622a-b are composed of aluminum-doped zinc sulfide (ZnS:Al), in polycrystalline form. ZnS has a band gap energy of about 3.66 eV, which is substantially higher than those of exemplary intrinsic layers (624a-b) and p-type layers (625a-b), whose band gap energies are in turn substantially higher than those of the primary cells 640a-d. The higher band gap energy of layers 622a-b relative to layers 624a-b and 625a-b results in the layers 622a-b functioning as windows for layers 624a-b, 625a-b, since some of the light transmitted by the layers 622a-b is absorbed by one or both of layers 624a-b, 625a-b. ZnS is particularly suitable as a window layer for use with an absorptive p-type layer 625a-b that comprises ZnTe, because ZnS is transparent to almost all of the solar spectrum, it can be made highly conductive (n-type) and it has a favorable conduction-band offset with ZnTe. In this regard it is desirable for the n-type layer to have a band gap energy of at least 3.5 eV or at least 3.6 eV. Semiconductor materials other than ZnS can, however, be used for the n-type layers 622a-b, such as ZnSe, ZnSSe, and MgZnSe, for example. Also, other n-type doping materials, as alternatives to aluminum, may also be used, such as Ga, In, F, Cl, Br, and I. Aluminum and chlorine are however particularly suitable as an n-type dopant because of the high conductivities that can be achieved.

In exemplary embodiments, the intrinsic layers 624a-b and the p-type layers 625a-b all comprise pure ZnTe or alloys of ZnTe having band gap energies of at least 2 eV, or at least 2.2 eV, or about 2.25 eV, or in a range from 2 to 3 eV, or from 2 to 2.5 eV, or from 2.2 to 2.3 eV, for reasons discussed elsewhere herein. Alloys of ZnTe in this regard may include, for example, CdZnTe, ZnSeTe, and ZnSTe, provided their band gap energies are suitably tailored. In the p-type layers 625a-b, the ZnTe-based material is doped with a suitable atomic species, e.g., N, P, As, or Cu, at a concentration that provides good conductivity. Nitrogen (N) is particularly suitable because of the high conductivity that can be achieved. The intrinsic layers 624a-b, particularly when composed of ZnTe-based materials, can be semi-insulating; therefore, in order to avoid losses due to electron-hole recombination and to enhance conversion efficiency, the intrinsic layers 624a-b are preferably kept relatively thin, e.g., less than 1000 nanometers thick, or in a range from 100 to 500 nm.

The optional n-type layers 623a-b may be included in order to provide an intermediate band gap energy between layers 622a-b and 624a-b for a graded effect. In an exemplary embodiment in which layers 622a-b comprise ZnS:Al and layers 624a-b comprise ZnTe, the layers 623a-b may comprise ZnSTe:Al. The use of a thin graded layer can reduce the effects of misfit dislocations and the heterobarrier on charge transport across the interface.

The anti-reflective layers 627a-b may be made by vapor-coating an optically transparent material of suitable refractive index and thickness to reduce surface reflection at the interface of the cells 620a-b with the encapsulant 615 over the wavelength range of light transmitted by the booster cells 627a-b and absorbed by the primary cells 640a-d. In some embodiments, the antireflective layers 627a-b may either or both comprise a multilayer dielectric stack.

Insulating structures 626a, 626b and conductive electrode structures 628a, 628b, 629c are provided as shown, using known patterning and deposition techniques, so as to connect the cells 620a, 620b in series. Electrodes 628a, 629c serve as output terminals for the array of booster cells. The array of primary cells 640a-d are similar in design to the booster cells, but are composed of different semiconductor materials. In view of the modeling results of FIGS. 5a-b, the primary cells 640a-d preferably comprise monocrystalline or multicrystalline silicon. Such primary cells are typically mounted on a substrate 641 composed of a polymer film, often referred to as a “back sheet”. Such polymer films are suitable and appropriate for use as substrates in solar panels that use silicon photovoltaic cells without any booster cells. However, in view of potential reliability issues associated with deterioration or contamination of thin films of polycrystalline II-VI materials, such as those used in the booster cells 620a, 620b, it may be advantageous to replace the polymer film substrate with a better barrier substrate so as to provide effective barrier substrates on both sides of the booster cells. Therefore, even in cases where the primary cells comprise monocrystalline or multicrystalline silicon, it may be advantageous for both the upper or front substrate 621 and the lower or back substrate 641 to comprise a glass sheet or layer of adequate thickness to provide a barrier to moisture or other contaminants, or to comprise another suitable barrier material or structure. Of course, to maintain a contaminant-free cavity, the periphery or edges of the panel 610 may also desirably be sealed for long-term stability of the panel.

In brief, the primary cells 640a, 640b, 640c, 640d comprise conductive electrodes 649, 648a, 648b, 648c, 648d, p-type layers 642a, 642b, 642c, 642d, n-type layers 643a, 643b, 643c, 643d, anti-reflective layers 647a, 647b, 647c, 647d, and insulating structures (not labeled) arranged as shown in the figure to provide a series connection of the four primary cells. Electrodes 649, 648d serve as output terminals for the array of primary cells.

In FIG. 6, the lateral in-plane dimension of each booster cell 620a, 620b is shown as being about two times the corresponding lateral dimension of each primary cell 640a, 640b, 640c, 640d. In general, we have found it can be advantageous to tailor the dimensions of the booster cells and the primary cells not only to maximize useful area and minimize wasted area, i.e., minimize the amount of light that impinges on the solar module without impinging on a booster cell or primary cell, but also to configure the array of booster cells to provide an output on its output terminals (e.g. terminals 628a, 629c in FIG. 6) that is substantially compatible with the output provided by the primary cells on its output terminals (e.g. terminals 649, 648d in FIG. 6). In some cases, the compatibility may be good enough so that the output terminals of the booster cells can be directly connected to the output terminals of the primary cells, to effectively provide a 2-wire device. The output provided by the booster cells can be made compatible with that provided by the primary cells by ensuring that the operating voltage (when the panel is fully illuminated, e.g., exposed to full sunlight such as a solar flux of one sun) across the output terminals of the booster cell array is substantially the same as the operating voltage (under the same illumination conditions) across the output terminals of the primary cell array. This condition can be satisfied by tailoring the areas of the various cells appropriately. To begin with, the areas of the booster cells are preferably substantially equal to each other (e.g. each having an area of A1) so that they each supply the same operating current. The areas of the primary cells are also preferably substantially equal to each other (e.g. each having an area of A2) so that they also supply the same operating current, this operating current typically being different from the current supplied by the booster cells.

Beyond this, the areas A1 and A2 can be selected as a function of the operating voltages Vₘₚ at maximum power dissipation (see discussion above) supplied by each booster cell and each primary cell. When the panel is fully illuminated, each booster cell provides a first operating voltage V1 at maximum power dissipation, and each primary cell provides a second operating voltage V2 at maximum power dissipation. The total voltage across the output terminals of the array of booster cells (which, in the case of FIG. 6, equals 2*V1) will substantially equal the total voltage across the output terminals of the array of primary cells (which, in the case of FIG. 6, equals 4*V2) if the quantity (V1/A1) is substantially equal to (V2/A2). For example, the parameters may satisfy the condition 0.8≦(V1*A2)/(V2*A1)≦1.2, or 0.9≧(V1*A2)/(V2*A1)≦1.1. In the case of FIG. 6, if, for example, polycrystalline ZnTe booster cells provide an operating voltage V1 of typically about 1.1 Volts, and monocrystalline and multicrystalline silicon primary cells provide an operating voltage V2 of typically from about 0.5 to 0.6 Volts, then V1/V2 is about 2 for this case, and A1/A2 is also preferably about 2, as depicted schematically in FIG. 6.

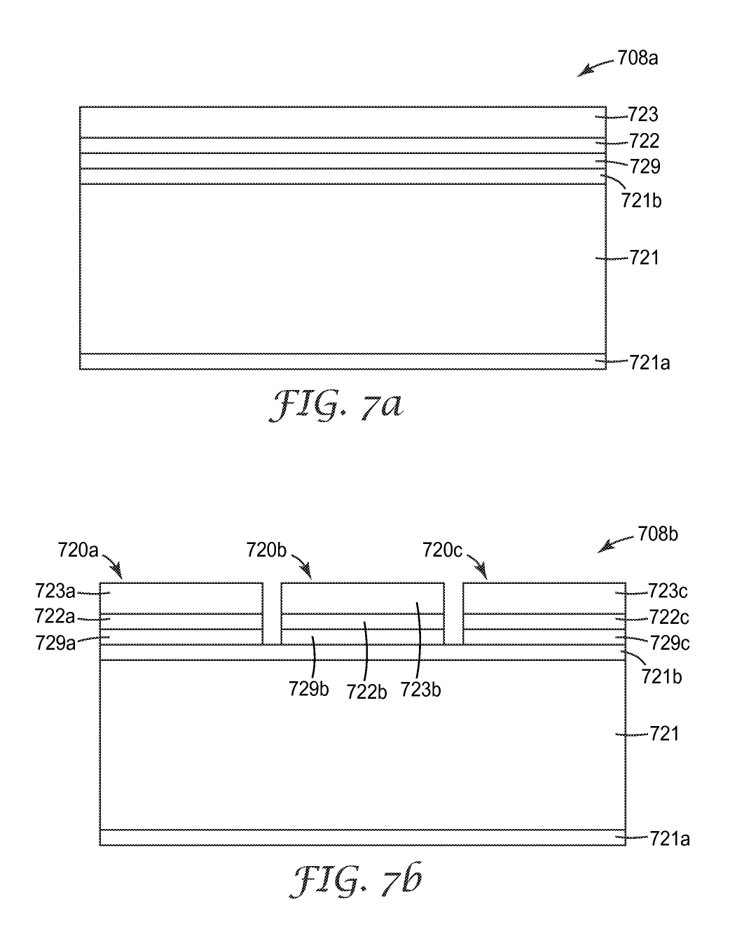

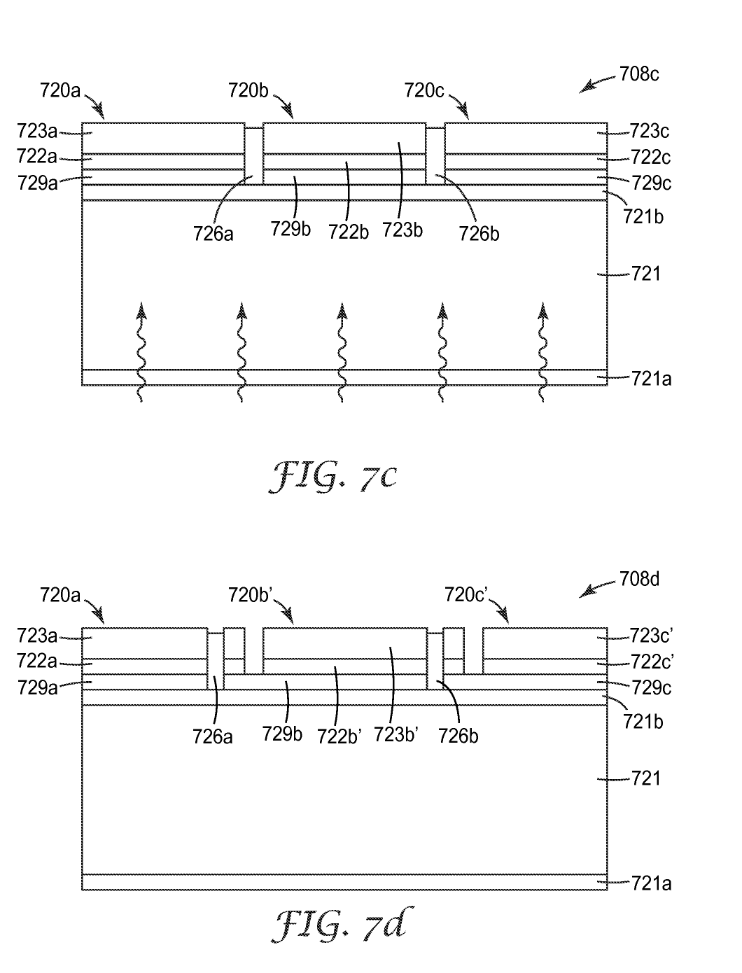

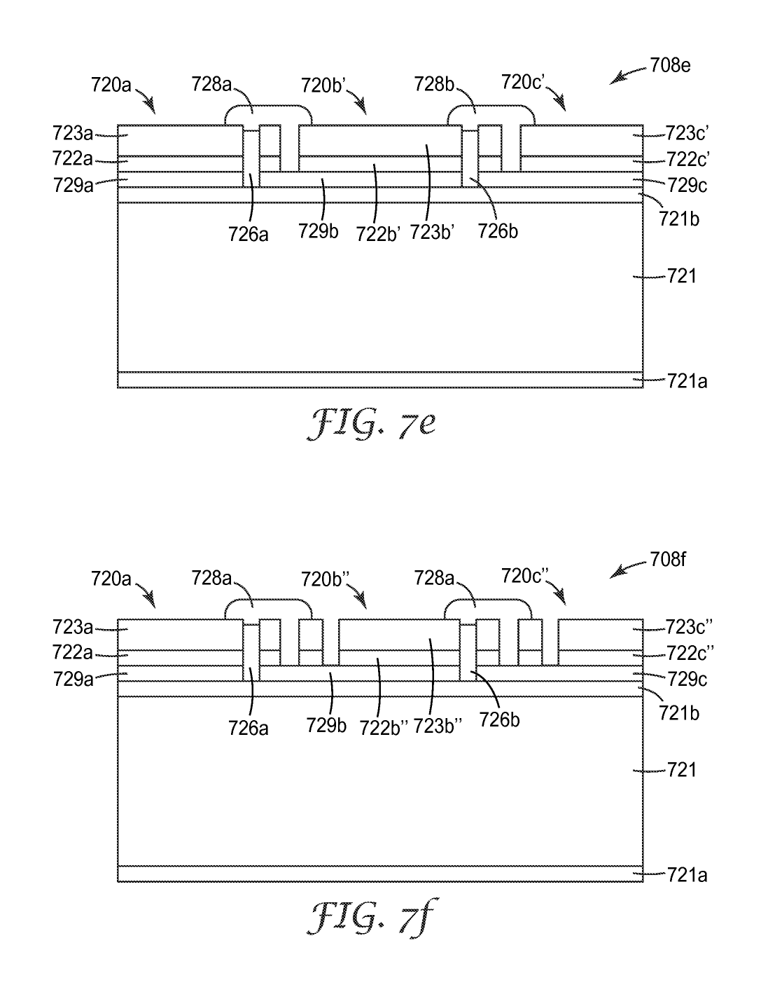

Turning now to FIGS. 7a-7f, we see there a series of schematic side or sectional views that show a booster cell component in various stages of manufacture. The manufacturing process depicted in these figures and described in connection therewith is only exemplary, and should not be construed to be unduly limiting. The finished booster cell component desirably has an array of booster cells disposed on a transparent glass or other suitable substrate, the component being configured for mating with an array of primary cells so as to provide a stacked solar module.

A glass substrate 721, suitable for use as the cover glass on a photovoltaic module, optionally with appropriate anti-reflective coatings 721a, 721b on its major surfaces, is first cleaned and a transparent conductor 729 is deposited on one surface. The transparent conductor 729 may comprise, for example, indium oxide, tin oxide, or zinc oxide, and may be deposited by any suitable technique, including sputtering, vacuum evaporation, or chemical vapor deposition. A layer of a first wide-band-gap II-VI semiconductor 722, preferably ZnS, is then deposited on the transparent conductor. This deposition may be done, for example, by close-spaced sublimation. This first II-VI semiconductor 722 is preferably doped n-type with a shallow donor impurity such at Al, Cl, or F. A layer of a second II-VI semiconductor 723 is then deposited on the first II-VI semiconductor 722. The second semiconductor 723 preferably comprises or preferably is ZnTe. At least a portion of this layer is preferably doped p-type using a shallow acceptor, such as N, P, or As. This deposition may be done, for example, by close-spaced sublimation. If nitrogen gas is used as a dopant source, a plasma may be used to degenerate excited species that are more readily incorporated in the growing ZnTe layer. The II-VI semiconductors 722, 723 may be thermally annealed after their deposition. The resulting component 708a is shown in FIG. 7a.

The deposited layers may then be patterned into numerous cells, which are typically connected in series in the finished product. The patterning may be carried out by mechanical scribing, laser scribing, and/or with photolithography and wet chemical or plasma etching. In this example, the pattering is achieved by using laser scribing to form grooves that extend through the transparent conductor 729, the first II-VI semiconductor 722, and the second semiconductor 723, thus providing isolated layers 729a, 729b, 729c of the transparent conductor 729, isolated layers 722a, 722b, 722c of the first II-VI semiconductor 722, and isolated layers 723a, 723c, 723d of the second II-VI semiconductor 723, the isolated layers forming groups of cells 720a, 720b, 720c. The resulting component 708b is shown in FIG. 7b.

Following this, insulating structures 726a, 726b are formed by applying an insulator to the grooves. The insulator may be applied by sputtering, vacuum evaporation, or chemical vapor deposition, and patterned by photolithography. Alternatively, the insulator may be or comprise a photo-curable polymer that is cured by exposure of ultraviolet light through the glass substrate 721. In this case, the II-VI semiconductor (see layers 722a, 722b, 722c, 723a, 723b, 723c) acts as a photomask so that the insulating polymer is only cured in the grooves. The uncured insulator is then washed away. The resulting component 708c is shown in FIG. 7c.

Next, vias (channels or holes) are formed adjacent to the grooves, through the II-VI semiconductors 722, 723 to provide electrical contact to the underlying transparent conductor. The vias may be formed by mechanical scribing, laser scribing, or with photolithography and wet chemical or plasma etching. In this example, laser scribing is used to ablate the II-VI semiconductors, exposing the transparent conductors 729b, 729c. The formation of the vias produces modified layers 722b′, 722c′, 723b′, and 723c′, which in turn produce modified cells 720b′, 720c′. Cell 720a remains unchanged. The resulting component 708d is shown in FIG. 7d.

Electrodes 728a, 728b are then applied over the insulator-filled grooves to make electrical contact to the transparent conductors 729b, 729c and to the second II-VI semiconductor layers 723a, 723b′ on the opposite side of the respective grooves. The electrodes 728a, 728b may be deposited by sputtering, vacuum evaporation, or chemical vapor deposition, and patterned by shadow masking or photolithography. Alternatively, in this example the electrode may be formed by screen printing a metal paste, such as Ag paste and subsequent annealing. The resulting component 708e is shown in FIG. 7e.

Finally, a portion of the second semiconductor 723 adjacent to the via and opposite the groove is removed to disconnect the electrode (728a, 728b) from the second semiconductor 723 of the adjacent cell. In this process, the first semiconductor 722 may also be optionally removed, although the transparent conductor 729 layer portions should remain. This step may be accomplished by mechanical scribing, laser scribing, or with photolithography and wet chemical or plasma etching. In this example, laser scribing is used to ablate both of the II-VI semiconductors, exposing the transparent conductor. This ablation produces modified layers 722b″, 723b″, 722c″, and 723c″, which in turn produce modified cells 720b″, 720c″. The resulting finished component 708f is shown in FIG. 7f. The adjacent cells 720a, 720b″, 720c″ can be seen to be connected in series. At this point, an antireflection coating may be applied to the semiconductor surface, and external wiring may be attached to the series-connected booster cells, and the glass and cells are ready to be installed as the cover glass in a photovoltaic module. Recall now the modeling described in connection with FIGS. 5a and 5b. That modeling investigated the suitability of various types of booster cells when combined with primary photovoltaic cells composed of monocrystalline silicon or multicrystalline silicon. We now repeat that modeling for cases in which the primary photovoltaic cell is composed not of silicon, but of thin-film cadmium telluride (CdTe).

Cadmium telluride-based photovoltaic cells made by thin film deposition on a glass substrate produce semiconductor (CdTe) layers have a polycrystalline morphology. Such cells have a band gap energy of about 1.45 eV, and have typical conversion efficiencies of about 12%. For the modeling, we assumed a stacked structure in which a booster cell was placed in front of the CdTe primary cell, and the combination was illuminated with light corresponding to the solar spectrum. The free variable used in the modeling was again the band gap energy of the booster cell, and the same modeling assumptions discussed above in connection with FIGS. 5a, 5b were again made, except that the primary cell comprised CdTe rather than Si.

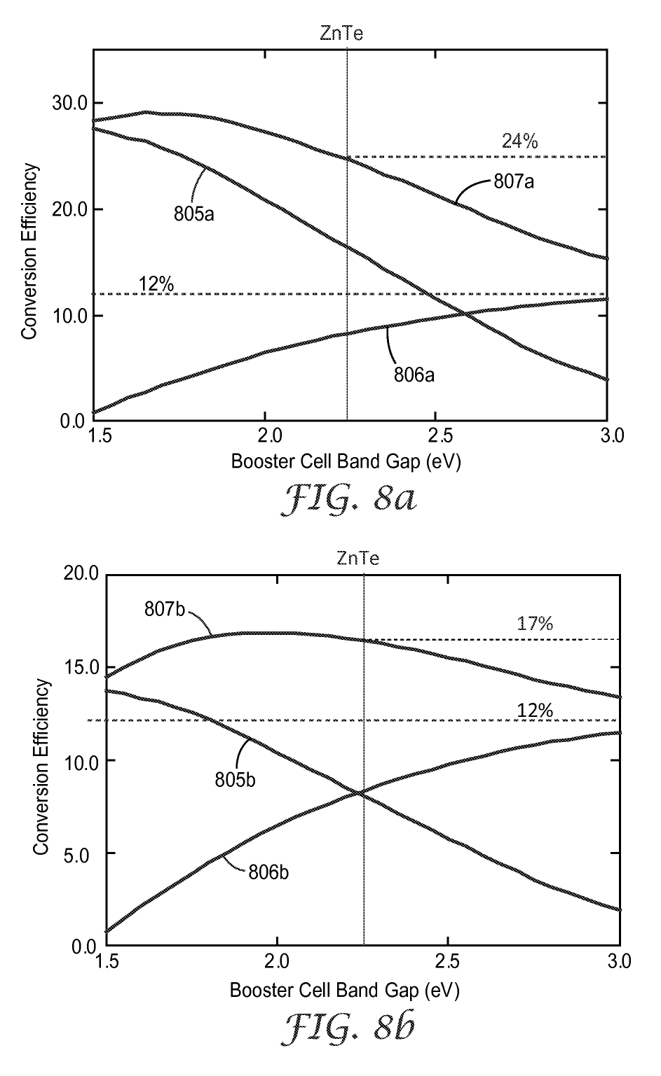

The model initially assumed the quantum efficiency of the booster cell was ideal, i.e., 100%. The results for this ideal case are shown in FIG. 8a. In this figure, curve 805a shows the conversion efficiency of the booster cell by itself, curve 806a shows the conversion efficiency of the primary (CdTe) cell by itself, and curve 807a shows the combined conversion efficiency for both cells. Several features of the curves are worth noting. Curve 806a for the primary cell has a value of zero at a booster cell band gap energy of 1.45 eV (slightly outside of the range shown in the figure). This is logical, because the band gap energy of the primary cell was assumed to be 1.45 eV, and if the booster cell band gap energy is also 1.45 eV, then none of the light transmitted by the booster cell (in this case, light whose wavelength is 855 nm or more) would be absorbed by the primary cell. Curve 806a also asymptotically approaches a conversion efficiency of 12% for increasing values of the booster cell band gap energy. This is also logical, because the conversion efficiency of the primary cell by itself was assumed to be 12%, and as the energy gap of the booster cell increases, it blocks (absorbs) less and less of the incident solar spectrum from reaching the primary cell.

We also include in FIG. 8a a vertical line at 2.25 eV, which is the band gap energy of bulk crystalline ZnTe. Note that the maximum conversion efficiency of about 30% for the combination of cells (curve 807a) occurs at a booster cell band gap energy of less than 1.75 eV, which is very much less than 2.25 eV. This result of FIG. 8a would therefore lead persons of ordinary skill in the art away from considering materials comprising ZnTe as a reasonable option for a booster cell for use with a CdTe primary cell, because of the non-optimal performance of the combination of those cells. The person of ordinary skill would be led away from using, with those primary cells, booster cell materials comprising

ZnTe and/or having a band gap energy of at least 2 eV, or at least 2.2 eV, or about 2.25 eV, or in a range from 2 to 3 eV, or from 2 to 2.5 eV, or from 2.2 to 2.3 eV.

Just as before, we continued our analysis to consider an alternative scenario, more realistic than the ideal case. We thus modeled an alternative stacked solar module in which a booster cell was again placed in front of a silicon primary cell (CdTe, band gap energy of 1.45 eV, solo conversion efficiency of 12%), and the combination was again illuminated with light corresponding to the solar spectrum. The free variable used in the modeling was again the band gap energy of the booster cell, and the model assumed the booster cell transmitted all light of energy below the band gap energy, and absorbed all light above the band gap energy. In this alternative scenario, however, the model assumed a quantum efficiency for the booster cell of 50% rather than 100%. Every two photons that were absorbed in the booster cell were thus assumed to generate one quantum (electron and hole) of collected charge.

The results for this alternative case (lossy booster cell with thin film CdTe primary cell) are shown in FIG. 8b. In this figure, curve 805b shows the conversion efficiency of the booster cell by itself, curve 806b shows the conversion efficiency of the primary (CdTe) cell by itself, and curve 807b shows the combined conversion efficiency for both cells. Several features of the curves are worth noting. Curve 806b for the primary cell again has a value of zero at a booster cell band gap energy of 1.45 eV (slightly outside of the range shown in the figure). This is to be expected using the same logic described above for FIG. 8a. Curve 806b also asymptotically approaches a conversion efficiency of 12% for increasing values of the booster cell band gap energy. This too is to be expected, based again on the logic described above for FIG. 8a.

Comparing FIGS. 8a and 8b, we also see that the maximum conversion efficiency for the combination of the booster cell and the primary cell in FIG. 8b, i.e., about 17%, is lower than that in FIG. 8a, i.e., about 30%. The lower efficiency value is logical based on the lossy booster cell assumed for FIG. 8b.

A more surprising difference between FIGS. 8a and 8b is the shift in the booster cell band gap energy at which the combination curves (807a, 807b) experience a maximum. In particular, the booster cell band gap energy that produces optimal conversion efficiency for the booster/primary cell combination shifts to substantially higher energies in FIG. 8b compared to FIG. 8a. The shift is such that the band gap energy of 2.25 eV, corresponding to non-alloy ZnTe, results in a conversion efficiency for the combination of cells that is near the peak of the curve 807b. We note from FIG. 8b that other materials comprising ZnTe that have somewhat different band gap energies, such as a band gap energy of at least 2 eV, or at least 2.2 eV, or about 2.25 eV, or in a range from 2 to 3 eV, or from 2 to 2.5 eV, or from 2.2 to 2.3 eV, would also produce relatively high overall conversion efficiency for the more realistic model of FIG. 8b. Band gap energies such as these may be achieved using alloys of ZnTe, e.g., materials that contain in the lattice structure one or more other atoms from columns II or VI of the periodic table, the other atoms substituting for some of the Zn and/or Te atoms in the lattice.

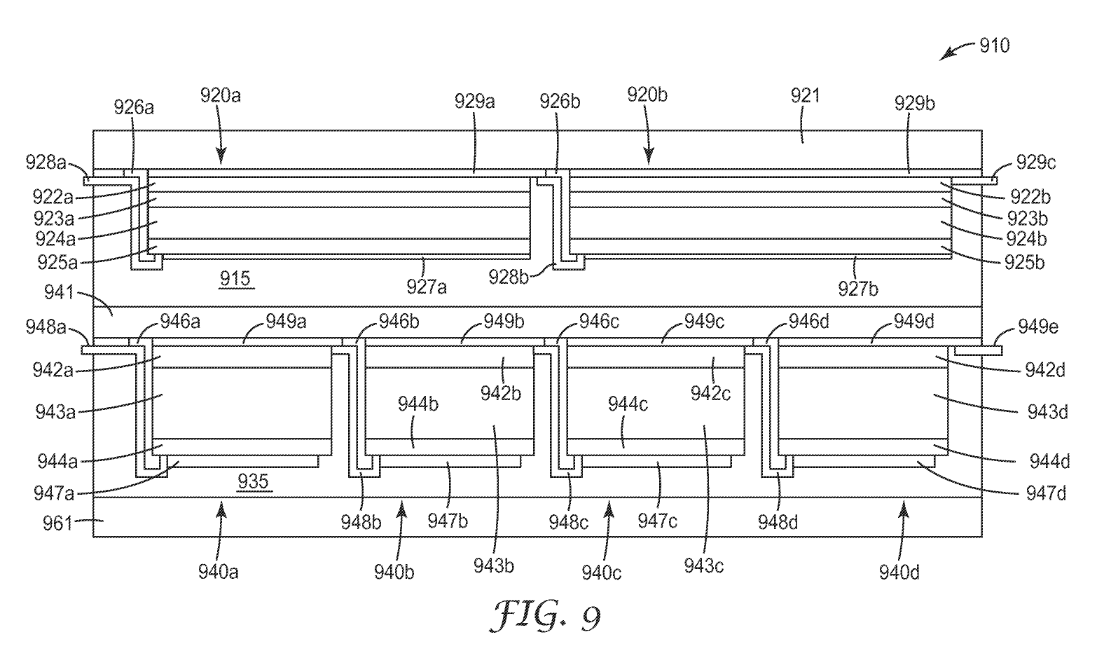

An exemplary solar module in which ZnTe-based booster cells are combined with primary photovoltaic cells in a stacked arrangement is shown schematically in FIG. 9. Similarities between this embodiment and that of FIG. 6 will be apparent to the reader, and features and advantages discussed in connection with FIG. 6 should be assumed to be applicable also to the embodiment of FIG. 9 unless otherwise indicated.

The solar module 910 can be considered to be the combination of a booster component, disposed at or near a front side of the module 910, and an array of primary solar cells 940a, 940b, 940c, 940d, disposed at or near a back side of the module. The booster component may comprise a transparent substrate 921, such as a rigid piece of glass or other suitable material, on which is formed an array or plurality of booster cells 920a, 920b. Although only two booster cells and four primary cells are shown in the figure, the reader will understand that the module can be designed to accommodate other numbers of booster cells and primary cells as desired.

A transparent encapsulant 915 may fill the space between the booster cells 920a, 920b and the primary cells 940a, 940b, 940c, 940d. Ethylene vinyl acetate (EVA) and polyvinyl butyral (PVB) are examples of materials that may be used as the encapsulant to achieve desired design functions, depending on system requirements and specifications.

The booster cells 920a, 920b may each comprise a transparent conductor 929a, 929b, an n-type layer 922a, 922b, an optional graded n-type layer 923a, 923b, an intrinsic layer 924a, 924b, a p-type layer 925a, 925b, and an anti-reflective layer or coating 927a, 927b, arranged as shown in the figure. These layers, along with insulating structures 926a, 926b and conductive electrode structures 928a, 928b, 929c, may be the same as or similar to the corresponding layers described in connection with FIG. 6, and the reader is referred to that description for brevity. Electrodes 928a, 929c serve as output terminals for the array of booster cells.

The array of primary cells 940a-d are similar in design to the booster cells, but are composed of different semiconductor materials. In view of the modeling results of FIGS. 8a-b, the primary cells 940a-d preferably comprise thin film polycrystalline CdTe. Such primary cells are typically mounted on a substrate 941 composed of a glass. The thin film CdTe cells may indeed be deposited on the glass substrate 941 using close-spaced sublimation (CSS). An additional substrate glass 961 may be provided so as to provide effective barrier substrates on both sides of the CdTe primary cells to prevent contamination or deterioration thereof, and another encapsulant material 935 may fill the space between the primary cells and the back substrate 961. Advantageously, the front glass substrate 921 and the middle glass substrate 941 may likewise provide effective barrier substrates on both sides of the ZnTe-based booster cells to prevent contamination or deterioration thereof. Of course, to maintain a contaminant-free cavities, the periphery or edges of the panel 910 may also desirably be sealed for long-term stability of the panel.

In brief, the primary cells 940a, 940b, 940c, 940d comprise rear conductive electrodes 949a, 949b, 949c, 949d, conductive linking electrodes 948a, 948b, 948c, 948d, n-type layers 942a, 942b, 942c, 942d, which typically comprise CdS, p-type layers 943a, 943b, 943c, 943d, which typically comprise CdTe, contact layers 944a, 944b, 944c, 944d, which typically comprise ZnTe:Cu, electrodes 947a, 947b, 947c, 947d, and insulating structures 946a, 946b, 946c, 946d arranged as shown in the figure to provide a series connection of the four primary cells. Electrodes 948a, 949e serve as output terminals for the array of primary cells.

Similar to FIG. 6, the lateral in-plane dimension of each booster cell 920a, 920b in FIG. 9 is shown as being about two times the corresponding lateral dimension of each primary cell 940a, 940b, 940c, 940d. As discussed elsewhere herein, we have found it advantageous to tailor the dimensions of the booster cells and the primary cells not only to maximize useful area and minimize wasted area, but also to configure the array of booster cells to provide an output on its output terminals (e.g. terminals 928a, 929c in FIG. 9) that is substantially compatible with the output provided by the array of primary cells on its output terminals (e.g. terminals 948a, 949e in FIG. 9). This can be achieved, as discussed above, by satisfy the condition 0.8≦(V1*A2)/(V2*A1)≦1.2, or 0.9≦(V1*A2)/(V2*A1)≦1.1, where A1 refers to the area of each booster cell, A2 refers to the area of each primary cell, V1 refers to the operating voltage of each booster cell at maximum power dissipation and for full illumination, and V2 refers to the operating voltage of each primary cell at maximum power dissipation and for full illumination. In the case of FIG. 9, polycrystalline ZnTe booster cells provide an operating voltage V1 of typically about 1.1 Volts, and polycrystalline CdTe primary cells provide an operating voltage V2 of typically from about 0.5 to 0.6 Volts. Since V1/V2 is about 2 for this case, A1/A2 is also preferably about 2, as depicted schematically in FIG. 9.

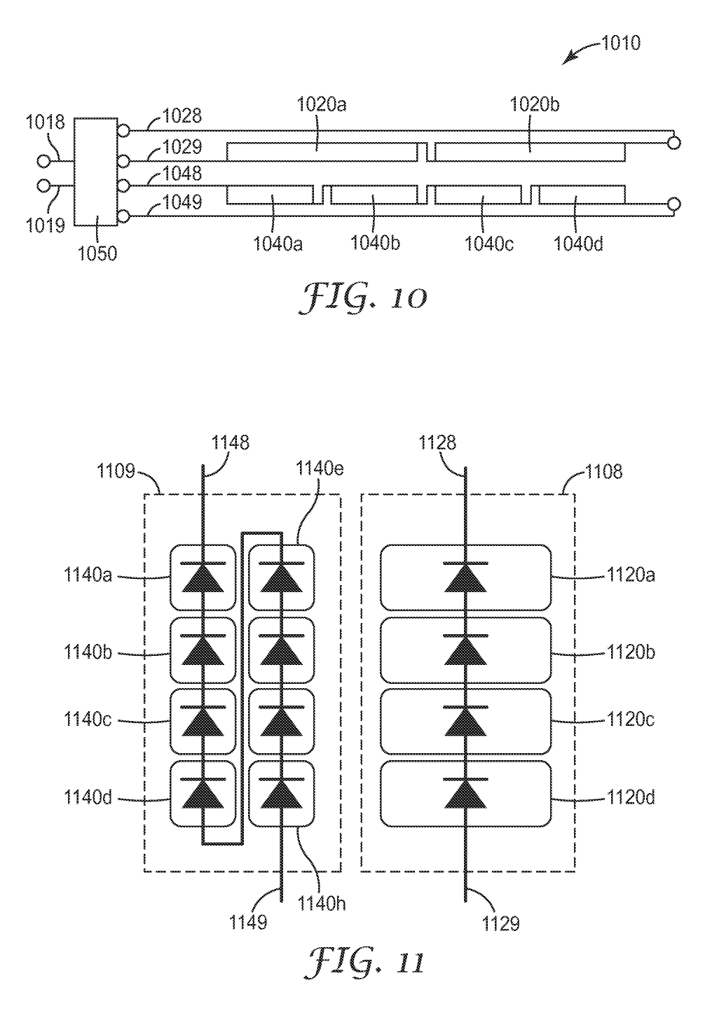

FIG. 10 is a schematic side or sectional view of a solar module 1010 having a plurality of stacked cells, showing electrical connections between cells and from the cells to a power combiner 1050. Booster cells 1020a, 1020b are positioned in front of an array of primary cells 1040a, 1040b, 1040c, 1040d. The booster cells may be any of the booster cells discussed herein, and the primary cells may also be any of the primary cells discussed herein. Although only two booster cells and four primary cells are shown, the reader will understand that other numbers of booster cells and primary cells may be used as desired. The individual booster cells are depicted as being wider (and having a greater area) than the individual primary cells, in order to provide an output for the booster cells that is substantially compatible with the output for the primary cells as discussed elsewhere herein, although such a design feature need not be implemented in the disclosed embodiments if so desired. The booster cells are connected in series between output terminals 1028, 1029, and the primary cells are connected in series between output terminals 1048, 1049. These terminals feed electrical power from the two arrays of cells to the power combiner 1050. In exemplary embodiment, the power combiner provides optimal load impedances across the respective terminals 1028/1029, 1048/1049, so as to derive maximum electrical power (Iₘₚ, Vₘₚ) from the respective arrays of cells, and efficiently converts the electrical power from the two circuits into a useful output over terminals 1018, 1019. In cases where the output from the booster cells is substantially compatible with the output from the primary cells, the power converter 1050 may simply be or comprise a passive component providing a direct connection between terminal 1018 and terminals 1028 and 1048, and providing another direct connection between terminal 1019 and terminals 1029, 1049. In other cases, the power combiner may include an inverter capable of proving power to an ac circuit.

FIG. 11 shows, in schematic plan view, an exemplary physical layout and circuit layout of a primary cell component 1109 and corresponding layouts of a booster cell component 1108, the components being adapted for use in a stacked solar module, and shown separated from each other for clarity. The component 1109 includes an array of primary photovoltaic cells 1140a through 1140h, such cells being connected in series between terminals 1148, 1149. The component 1108 includes an array of booster photovoltaic cells 1120a through 1120d, such cells being connected in series between terminals 1128, 1129. The booster cells and primary cells may be or comprise any of such cells discussed elsewhere herein. The spatial arrangement of the cells may be substantially as depicted in the figure. For example, the booster cells may have individual areas that are about two times the individual areas of the primary cells, and each booster cell may be in substantial registration with two underlying primary cells when the component 1108 is positioned in front of component 1109. For example, booster cell 1120a may be in substantial registration with primary cells 1140a, 1140e, and booster cell 1120d may be in substantial registration with primary cells 1140d, 1140h.

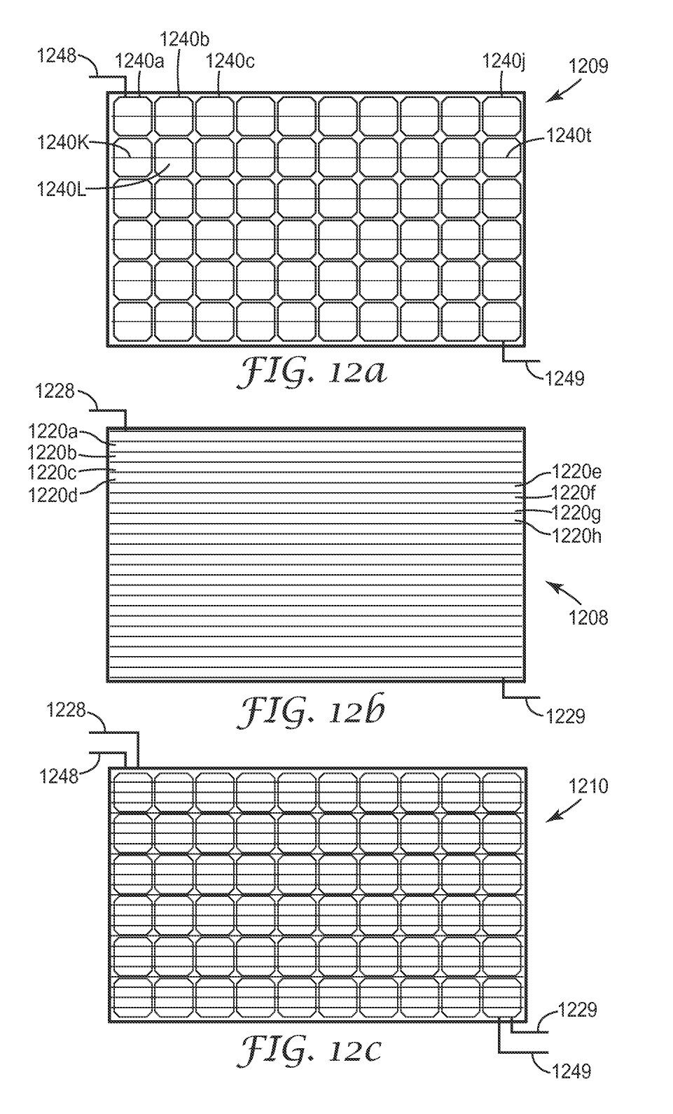

FIG. 12 shows, in schematic plan view, the physical layout of a primary cell component 1209, a booster cell component 1208, and the combination thereof in a stacked solar module 1210. The component 1209 includes an array of sixty primary photovoltaic cells, some of which are labeled 1240a through 1240j, some of which are labeled 1240k through 1240t. These cells may all be connected in series, or they may be connected in other arrangements as desired, between terminals 1248, 1249. The component 1208 includes an array of twenty-four booster photovoltaic cells, some of which are labeled 1220a through 1220d, and some of which are labeled 1220e through 1220h. These cells may all be connected in series, or they may be connected in other arrangements as desired, between terminals 1228, 1229. The booster cells and primary cells may be or comprise any of such cells discussed elsewhere herein. The spatial arrangement of the cells may be substantially as depicted in the figure. For example, the booster cells may have individual areas such that four of the stripe-shaped booster cells are in substantial registration with one complete row of ten square-shaped primary cells when the booster cell component 1208 is positioned in front of the primary cell component 1209. Thus, in the module 1210, booster cells 1220a through 1220d are in substantial registration with the row of primary cells ranging from cell 1240a through 1240j, and the booster cells 1220e through 1220h are in substantial registration with the row of primary cells ranging from cell 1240k through cell 1240t. In such embodiment, the area A1 of the booster cell relative to the area A2 of the primary cell is in a ratio of A1/A2=10/4, or 2.5. By tailoring the widths of the stripe-shaped booster cells, other suitable ratios of the areas A1, A2 can be readily achieved. In cases where the output from the booster cells is substantially compatible with the output from the primary cells, the terminals 1228, 1248 may be connected directly together, and the terminals 1229, 1249 may be connected directly together. In such cases in which the booster cells circuit is connected in parallel with the primary cell circuit, it may be prudent to design the system so that the maximum-power voltage for the booster cell circuit is somewhat larger than that of the primary cell circuit. In this way the booster cells will not limit the performance of the system at various times of day or weather conditions. For the case of series-connected booster cells in parallel with series-connected primary cells, this implies 1.0≦(V1*A2)/(V2*A1).

The foregoing embodiments are only some of the many embodiments that will be apparent to the skilled person upon reading the present disclosure, and many extensions of the disclosed embodiments and ideas will be apparent to such person. For example, the disclosed booster cells and primary cells may also be used in embodiments that include more than two stacked arrays of cells, e.g., three stacked arrays of cells, or four stacked arrays of cells. Unless otherwise indicated, all numbers expressing feature sizes, amounts, physical properties, and so forth used in the specification and claims are to be understood as being modified by the term “about”. Accordingly, unless indicated to the contrary, the numerical parameters set forth in the specification and claims are approximations that can vary depending on the desired properties sought to be obtained by those skilled in the art utilizing the teachings of the present application. Various modifications and alterations of this invention will be apparent to those skilled in the art without departing from the scope and spirit of this invention, and it should be understood that this invention is not limited to the illustrative embodiments set forth herein. All U.S. patents, published and unpublished patent applications, and other patent and non-patent documents referred to herein are incorporated by reference, to the extent they do not directly contradict the foregoing disclosure.

1. A component for use in a solar module, the component comprising:
a transparent glass substrate; and
a thin-film photovoltaic booster cell formed on the substrate, the booster cell comprising an n-type layer and a p-type layer, the n-type layer comprising polycrystalline zinc sulfide (ZnS) and having a band gap energy of at least 3.5 eV, and the p-type layer comprising polycrystalline zinc telluride (ZnTe);
wherein the booster cell is adapted to generate electricity by absorbing solar radiation in a first wavelength range, the booster cell also being adapted to transmit solar radiation in a second wavelength range greater than the first wavelength range.

2. The component of claim 1, wherein the p-type layer has a band gap energy of at least 2 eV.

3. (canceled)

4. The component of claim 3, wherein the p-type layer has a band gap energy in a range from 2. 2 to 2.3 eV.

5. The component of claim 1, wherein in the n-type layer, the polycrystalline ZnS is doped with aluminum (Al) or chlorine (Cl), and in the p-type layer, the polycrystalline ZnTe is doped with nitrogen (N).

6. The component of claim 1, wherein the booster cell also comprises an intrinsic layer disposed between the n-type layer and the p-type layer, the intrinsic layer comprising polycrystalline ZnTe.

7. The component of claim 6, wherein the intrinsic layer has a band gap energy in a range from 2.2 to 2.3 eV.

8. (canceled)

9. The component of claim 1, wherein the booster cell is one of an array of booster cells formed on the substrate, each of the booster cells comprising an n-type layer comprising polycrystalline ZnS and a p-type layer comprising polycrystalline ZnTe.

10. A solar module, comprising:
the component of claim 9; and
an array of photovoltaic primary cells disposed to receive solar radiation transmitted by the component, the primary cells each being adapted to generate electricity by absorbing solar radiation in the second wavelength range.

11. The module of claim 10, wherein the array of primary cells comprise monocrystalline silicon, multicrystalline silicon, and/or polycrystalline cadmium telluride.

12. A solar module, comprising:
an array of photovoltaic booster cells adapted to generate electricity by absorbing solar radiation in a first wavelength range, the booster cells also being adapted to transmit solar radiation in a second wavelength range greater than the first wavelength range; and
an array of photovoltaic primary cells disposed to receive solar radiation transmitted by the array of booster cells, the primary cells each being adapted to generate electricity by absorbing solar radiation in the second wavelength range;
wherein the booster cells comprise polycrystalline zinc telluride (ZnTe); and
wherein the primary cells comprise monocrystalline silicon, multicrystalline silicon, and/or polycrystalline cadmium telluride.

13. The module of claim 12, wherein each booster cell includes a p-type layer comprising polycrystalline zinc telluride (ZnTe) and having a band gap energy of at least 2 eV.

14. The module of claim 13, wherein the p-type layer of each booster cell has a band gap energy of at least 2.2 eV.

15. The module of claim 14, wherein the p-type layer of each booster cell has a band gap energy in a range from 2.2 to 2.3 eV.

16. The module of claim 12, wherein each booster cell includes an n-type layer comprising polycrystalline zinc sulfide (ZnS) and a p-type layer comprising polycrystalline zinc telluride (ZnTe).

17. The module of claim 16, wherein the n-type layer has a band gap energy of at least 3.5 eV, and the p-type layer has a band gap energy of at least 2 eV.

18. The module of claim 16, wherein in the n-type layer, the polycrystalline ZnS is doped with aluminum (Al) or chlorine (Cl), and in the p-type layer, the polycrystalline ZnTe is doped with nitrogen (N).

19. The module of claim 16, wherein each booster cell also includes an intrinsic layer disposed between the n-type layer and the p-type layer, the intrinsic layer comprising polycrystalline ZnTe.

20. (canceled)

21. The module of claim 12, further comprising:
a first glass substrate on which the array of booster cells is disposed; and
a second substrate on which the array of primary cells is disposed.

22. The module of claim 21, wherein the primary cells comprise monocrystalline silicon, multicrystalline silicon, and/or polycrystalline cadmium telluride (CdTe).

23. The module of claim 12, wherein the array of booster cells is connected in parallel with the array of primary cells.
